(19) United States
(12) Patent Application Publication
(10) Pub. No.: US 2025/0055169 A1
(43) Pub. Date: Feb. 13, 2025

(54) CONNECTING DEVICE, TESTING DEVICE, AND COMMUNICATION DEVICE

(71) Applicant: ADVANTEST CORPORATION, Tokyo (JP)

(72) Inventor: Takahiro TSUSHIMA, Tokyo (JP)

(21) Appl. No.: 18/931,093

(22) Filed: Oct. 30, 2024

Related U.S. Application Data
(63) Continuation of application No. PCT/JP2022/028991, filed on Jul. 27, 2022.

(51) Int. Cl. H01P 1/15; G01R 31/28

(52) U.S. Cl. CPC H01P 1/15; G01R 31/28

(57) ABSTRACT

A connecting device, including: a first connecting unit that switches a connection between a first terminal and a second terminal; and a second connecting unit that switches a connection between the first terminal or the second terminal and a third terminal, wherein the first connecting unit has: a first transmission line; a first connection switching unit that switches the connection between the first terminal and the second terminal via the first transmission line; and a first ground switching unit that switches a connection of each of three or more first connection points at different positions in the first transmission line to a reference potential.

### BACKGROUND

### 1. Technical Field

The present invention relates to a connecting device, a testing device and a communication device.

### 2. Related Art

In Patent Document 1, it is described that “an attenuation device attenuates a signal received from a first terminal and sends it out from the second terminal, comprising a first transmission line and a second transmission line with different signal attenuation amounts, a connection switching unit that switches a connection of either of the first transmission line or the second transmission line between the first terminal and the second terminal, and a first ground switching unit that connects two ends of the first transmission line as well as a contact point located on a line between the two ends of the first transmission line to a reference potential when the second transmission line is electrically connected between the first terminal and the second terminal” (claim 1) and “as shown in FIG. 2, the first transmission line 30 is divided into a plurality of sections 31, 32, 33 by switches of a first ground switching unit 40. Each switch of the first ground switching unit 40 may be arranged so that each of the sections 31, 32, 33 of the first transmission line 30 has an identical characteristic impedance. For example, the characteristic impedance of the first transmission line 30 is uniform in a state without the first ground switching unit 40, and when the capacitance component in an off state of each switch in the first ground switching unit 40 is substantially identical, each switch of the first ground switching unit 40 may be arranged with a substantially equal interval” (paragraph 0030 to 0031).

In Patent Document 2, it is described that “a high-frequency switch is characterized in: a first switch circuit in which a first λ/4 transmission line and a circuit including one or more first PIN diodes are connected in series is connected in parallel to the first λ/4 signal transmission line that transmits the transmission signal from the transmission terminal, in a high-frequency switch in which a second switch circuit consisting of a second λ/4 transmission line and a circuit including one or more second PIN diodes are connected in series is connected in parallel to a second λ/4 signal transmission line that transmits a received signal to a receiving terminal, at least a third switch circuit in which a third λ/4 transmission line and a circuit including one or more third PIN diodes are connected in series is connected in parallel to the third λ/4 signal transmission line connected between the receiving terminal and the second λ/4 signal transmission line, and a termination forming resistor is connected in parallel to the third PIN diode.”

### PRIOR ART DOCUMENTS

### Patent Documents

Patent Document 1: International Publication No. 2009/040990
Patent Document 2: Japanese Patent Application Publication No. 2009-239818

### BRIEF DESCRIPTION OF THE DRAWINGS

FIG. 1 illustrates a configuration of a connecting device 100 according to the present embodiment.

FIG. 2 illustrates a circuit configuration of a connecting device 200 that is a comparative example.

FIG. 3 illustrates a circuit configuration of the connecting device 100 according to the present embodiment.

FIG. 4 illustrates an equivalent circuit of a first connecting unit 110 in a connected state between connecting terminals P1 and P2 according to the present embodiment.

FIG. 5 illustrates an equivalent circuit of the first connecting unit 110 in a disconnected state between the terminals P1 and P2 according to the present embodiment.

FIG. 6 illustrates a circuit configuration of a connecting device 600 according to a first modification example in the present embodiment.

FIG. 7 illustrates a circuit configuration of a connecting device 700 according to a second modification example in the present embodiment.

FIG. 8 illustrates a circuit configuration of a connecting device 785 according to a third modification example in the present embodiment.

FIG. 9 illustrates a circuit configuration of a connecting device 800 according to a fourth modification example in the present embodiment.

FIG. 10 illustrates a configuration of a communication device 900 according to a fifth modification example in the present embodiment.

FIG. 11 illustrates a configuration of a testing device 1000 according to a sixth modification example in the present embodiment.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

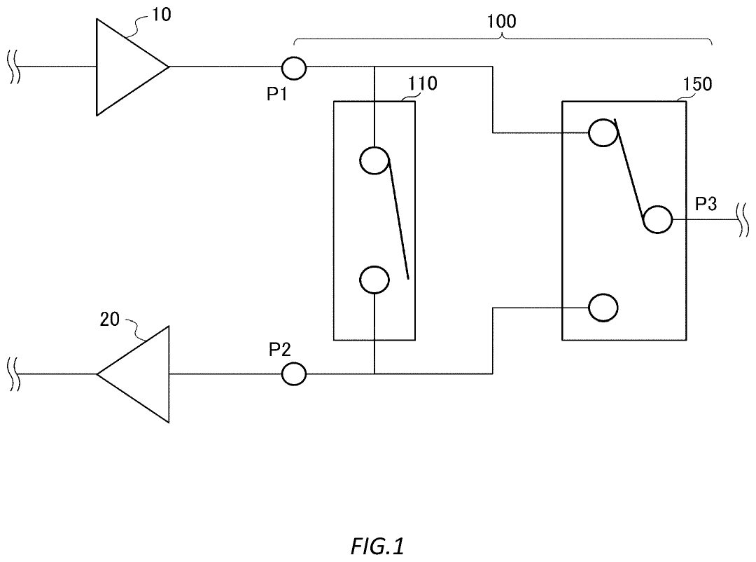

FIG. 1 illustrates a configuration of a connecting device 100 according to the present embodiment. The connecting device 100 includes a first terminal P1, a second terminal P2 and a third terminal P3 (also represented as “terminal P1”, “terminal P2” and “terminal P3” in the following).

The connecting device 100 functions as a switching device that switches an input/output path of a signal such as a high-frequency signal (an RF signal) of an analog for example between the terminals P1 to P3. As an example, the connecting device 100 may be used in an RF front end that switches a transmitting system circuit that outputs a transmission signal and a receiving system circuit that inputs a received signal. In this case, the terminal P1 is connected to the transmitting system circuit. An amplifier 10 that amplifies the transmission signal from the transmitting system circuit to supply it to the terminal P1 may be arranged between the transmitting system circuit and the terminal P1. The terminal P2 may be connected to the receiving system circuit. An amplifier 20 that amplifies the received signal from the terminal P2 to supply it to the receiving system circuit may be arranged between the receiving system circuit and the terminal P2. The terminal P3 is connected to a device or a circuit that transmits the transmission signal or receives the received signal.

The connecting device 100 transmits the transmission signal from the terminal P1 to the terminal P3 when being electrically connected between the terminals P1 and P3. The connecting device 100 transmits the received signal from the terminal P3 to the terminal P2 when being electrically connected between the terminals P2 and P3. The connecting device 100 transmits the transmission signal from the terminal P1 to the terminal P2 when being electrically connected between the terminals P1 and P2. This allows the connecting device 100 to loop back or feed back the transmission signal from the transmitting system circuit to the receiving system circuit when the terminal P1 is connected to the transmitting system circuit and the terminal P2 is connected to the receiving system circuit. Note that, in the present specification, a word “connected” used hereinafter means “electrically connected” unless specifically noted, and its meaning is not only limited to a direct electrical connection between components but also an indirect electrical connection including another component connected between components.

In the present embodiment, the connecting device 100 includes a first connecting unit 110 and a second connecting unit 150. The first connecting unit 110 is a switch that switches the connection between the terminal P1 and the terminal P2. The second connecting unit 150 is a switch that switches the connection between the terminal P1 or terminal P2 and the terminal P3.

The connecting device 100 according to the present embodiment is achieved by adding the first connecting unit 110 that is an SPST (Single Pole Single Throw) switch to an SPDT (Single Pole Double Throw) switch that functions as the second connecting unit 150, instead of using three SPDT switches of an identical configuration of an SPDT switch that switches the connection between the terminal P1 and the second connecting unit 150 or a loop back path, an SPDT switch that switches the connection between the terminal P2 and the second connecting unit 150 or a loop back path, and an SPDT switch that functions as the second connecting unit 150. This allows the connecting device 100 to reduce the implementing area on the board and enable high-density implementation compared to a case where it is achieved by using the three SPDT switches of the identical configuration.

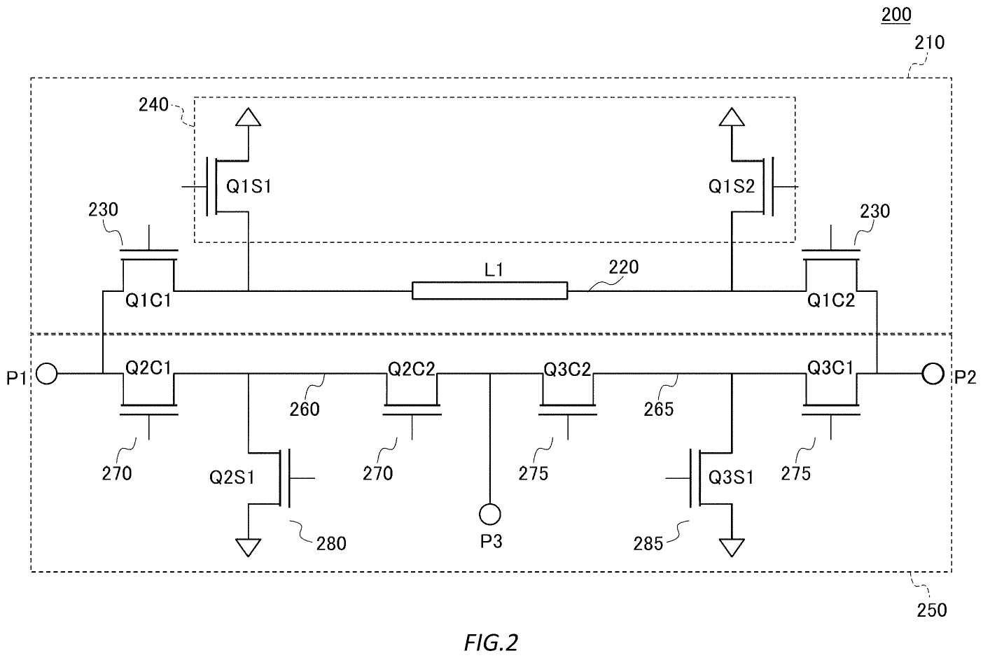

FIG. 2 illustrates a circuit configuration of a connecting device 200 in a comparative example. The connecting device 200 is an implementation example of the connecting device 100 in FIG. 1. The connecting device 200 includes a first connecting unit 210 that functions as the first connecting unit 110 and a second connecting unit 250 that functions as the second connecting unit 150.

The first connecting unit 210 has a first transmission line 220, a first connection switching unit 230 and a first ground switching unit 240. The first transmission line 220 functions as a loop back path that transmits the transmission signal from the terminal P1 to the terminal P2 as a result of being electrically connected between the terminal P1 and the terminal P2.

The first connection switching unit 230 switches the connection between the terminal P1 and the terminal P2 via the first transmission line 220. The first connection switching unit 230 includes a switch Q1C1 that switches the connection between the terminal P1 and the first transmission line 220, and a switch Q1C2 that switches the connection between the terminal P2 and the first transmission line 220.

The first ground switching unit 240 switches the connection of each of the end on the terminal P1 side and the end on the terminal P2 side in the first transmission line 220 to the reference potential. The first ground switching unit 240 includes a shunt-type switch Q1S1 that switches the connection of the end on the terminal P1 side in the first transmission line 220 to the reference potential, and a shunt-type switch Q1S2 that switches the connection of the end on the terminal P2 side in the first transmission line 220 to the reference potential. Herein, the reference potential may be a fixed potential such as ground potential (0 V).

The second connecting unit 250 has a second transmission line 260, a third transmission line 265, a second connection switching unit 270, a third connection switching unit 275, a second ground switching unit 280 and a third ground switching unit 285. The second transmission line 260 functions as a path that electrically connects between the terminal P1 and the terminal P3. The third transmission line 265 functions as a path that electrically connects between the terminal P2 and the terminal P3.

The second connection switching unit 270 switches the connection between the terminal P1 and the terminal P3 via the second transmission line 260. In the example in the present drawing, the second connection switching unit 270 includes a switch Q2C1 that switches the connection between the terminal P1 and the second transmission line 260, a switch Q2C2 that switches the connection between the terminal P3 and the second transmission line 260.

The third connection switching unit 275 switches the connection between the terminal P2 and the terminal P3 via the third transmission line 265. In the example in the present drawing, the third connection switching unit 275 includes a switch Q3C1 that switches the connection between the terminal P2 and the third transmission line 265, and a switch Q3C2 that switches the connection the terminal P3 and the third transmission line 265.

The second ground switching unit 280 includes a shunt-type switch Q2S1 that switches the connection of the end on the terminal P1 side in the second transmission line 260 to the reference potential. The third ground switching unit 285 includes a shunt-type switch Q3S1 that switches the connection of the end on the terminal P2 side in the third transmission line 265 to the reference potential.

Each switch included in the first connecting unit 210 and the second connecting unit 250 may be a semiconductor switching element such as a MOSFET (Metal Oxide Semiconductor Field Effect Transistor). Such a semiconductor switch has a first main terminal and a second main terminal, and a control terminal that controls a state of the connection between the first main terminal and the second main terminal. When the semiconductor switch is a MOSFET, the semiconductor switch has a drain and a source as the first main terminal and the second main terminal, and has a gate as the control terminal. The control terminal of each switch is connected to the control circuit that controls the switching of the connecting device 200, and each switch is controlled by the control circuit.

Herein, the connecting device 100 is desired to have a loop back path with wideband and high isolation characteristics when the loop back path is deactive (when terminals P1 and P2 are electrically disconnected). The connecting device 100 is desired to have a loop back path with wideband and low loss characteristics when the loop back path is active (when terminals P1 and P2 are electrically connected).

That is, the first connecting unit 110 is desirable to have high isolation characteristics to prevent transmission leakage of the transmission signal to the receiving system circuit to prevent damage or loss of sensitivity of the receiving system circuit when the loop back path is deactive. Herein, when the connecting device 100 is achieved with three discrete SPDT switch components of the identical configuration, sufficient physical distance is maintained between the SPDT switch components, and the isolation characteristics of the loop back path are often sufficient.

In contrast, if the loop back path of the connecting device 100 is achieved by the first connecting unit 110, the various elements and transmission lines are close together, in particular when the connecting device 100 is densified, and the isolation characteristics deteriorate. In the first connecting unit 210 in FIG. 2, shunt-type switches Q1S1 and Q1S2 are arranged in the loop back path to improve the isolation characteristics of the loop back path.

Herein, the shunt-type switches Q1S1 and Q1S2 are desirable to have smaller on-resistances to improve the isolation characteristics of the loop back path. However, switching elements with smaller on-resistances have larger gate widths and larger parasitic capacitances when off. As a result, if the parasitic capacitance of the switching element shunt-connected to the first transmission line 220 with parasitic inductance increases, the impedance of the loop back path when the loop back path is active decreases and the loss characteristics of the signal looped back from the transmitting system circuit to the receiving system circuit deteriorate.

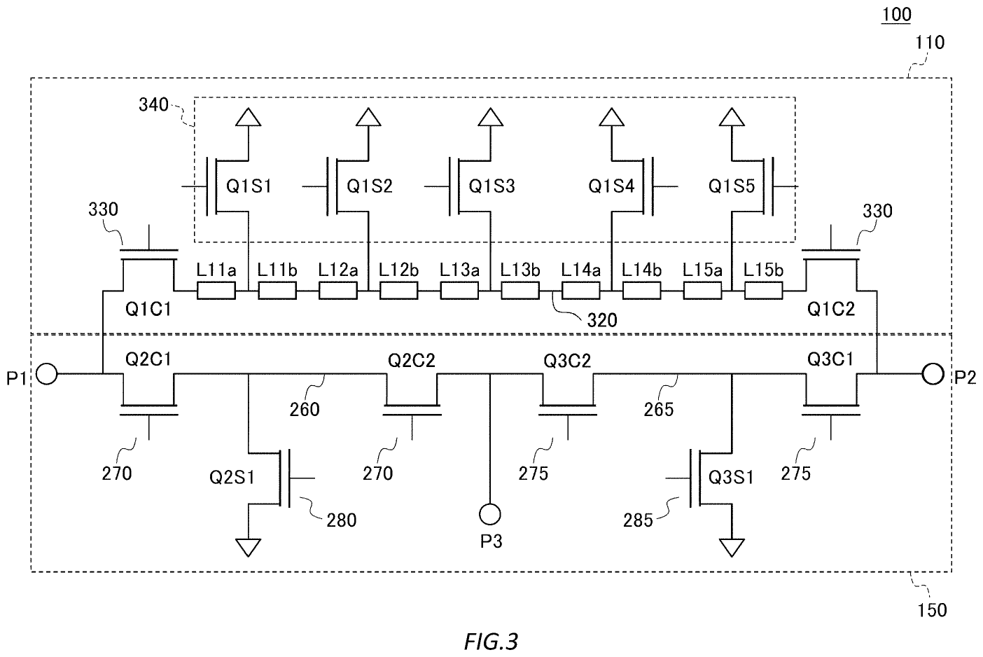

FIG. 3 illustrates a circuit configuration of the connecting device 100 according to the present embodiment. The connecting device 100 includes the first connecting unit 110 and the second connecting unit 150. Herein, the second connecting unit 150 has the same configuration as the second connecting unit 250 in FIG. 2, so the explanation is omitted except for the following differences. The first connecting unit 110 improves the isolation characteristics when the loop back path is deactive and the loss characteristics when the loop back path is active compared to the first connecting unit 210 in FIG. 2.

The first connecting unit 110 has a first transmission line 320, a first connection switching unit 330 and a first ground switching unit 340. The first transmission line 320 functions as a loop back path that transmits the transmission signal from the terminal P1 to the terminal P2 as a result of the electrical connection between the terminal P1 and the terminal P2.

The first connection switching unit 330 switches the connection between the terminal P1 and the terminal P2 via the first transmission line 320. The first connection switching unit 330 includes a switch Q1C1 that switches the connection between the terminal P1 and the first transmission line 320, and a switch Q1C2 that switches the connection between the terminal P2 and the first transmission line 320.

The first ground switching unit 340 switches the connection of each of the three or more first connection points at different positions in the first transmission line 320 to the reference potential. The first ground switching unit 340 has three or more first switching elements that connect or disconnect between each of the three or more first connection points and the reference potential. In the example in the present drawing, the first ground switching unit 340 includes shunt-type switches Q1S1, S1S2, Q1S3, Q1S4 and Q1S5 arranged between each of five first connection points at different positions in the first transmission line 320 and the reference potential. The shunt-type switches Q1S1 to Q1S5 are examples of the first switching element.

Each switch included in the first connecting unit 110 and the second connecting unit 150 may be a semiconductor switching element such as a MOSFET, similar to each switch included in the first connecting unit 210 and the second connecting unit 250 in FIG. 2. The control terminal of each switch is connected to the control circuit that controls the switching of the connecting device 200, and each switch is controlled by the control circuit.

When connecting between the terminals P1 and P2, the first connection switching unit 330 turns on switches Q1C1 to Q1C2 and the first ground switching unit 340 turns off switches Q1S1 to Q1S5 under control by the control circuit. In the second connecting unit 150, the second connection switching unit 270 turns off switches Q2C1 to Q2C2, the third connection switching unit 275 turns off the switches Q3C1 to Q3C2, the second ground switching unit 280 turns on the switch Q2S1, and the third ground switching unit 285 turns on a switch Q2S2.

When not connecting between the terminals P1 and P2, the first connection switching unit 330 turns off switches Q1C1 to Q1C2 and the first ground switching unit 340 turns on switches Q1S1 to Q1S5 under control by the control circuit. As a result, the first ground switching unit 340 connects each of three or more first connection points to the reference potential when there is no connection between the terminal P1 and the terminal P2.

When connecting between the terminals P1 and P3, under control by the control circuit, the second connection switching unit 270 turns on the switches Q2C1 to Q2C2, the third connection switching unit 275 turns off the switches Q3C1 to Q3C2, the second ground switching unit 280 turns off the switch Q2S1, and the third ground switching unit 285 turns on the switch Q2S2. When connecting between the terminals P2 and P3, under control by the control circuit, the second connection switching unit 270 turns off the switches Q2C1 to Q2C2, the third connection switching unit 275 turns on the switches Q3C1 to Q3C2, the second ground switching unit 280 turns on the switch Q2S1 and the third ground switching unit 285 turns off the switch Q2S2. In this manner, the second connecting unit 150 switches the connection of the terminal P3 to either of the terminal P1 or the terminal P2 when there is no connection between the terminal P1 and the terminal P2.

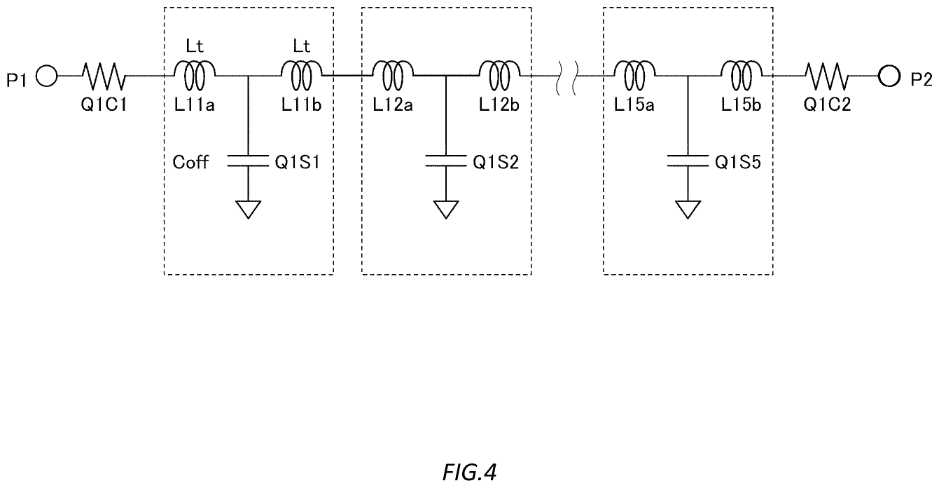

FIG. 4 illustrates a equivalent circuit in a connected state between the terminals P1 and P2 of the first connecting unit 110 according to the present embodiment. In a connected state between the terminals P1 and P2, the switches Q1C1 to Q1C2 are turned on and can be equivalently represented as resistors with resistance values corresponding to their on-resistances. The switches Q1S1 to Q1S5 are turned off and can be equivalently represented as capacitors with a capacitance value Coff corresponding to the parasitic capacitance when off.

The first transmission line 320 as a whole has a characteristic impedance higher than a characteristic impedance Z0 (for example, 50Ω) of the external transmission line connected to the terminal P1 (the circuit and transmission line connected to the transmitting system circuit or the amplifier 10) due to the inductive components L11a to L15b. The first transmission line 320 is divided into sections with inductive components L11a to b, sections with inductive components L12a to b, . . . , sections with inductive components L15a to b, with first connection points within each section. Herein, each of the inductive components L11a to b, L12a to b, . . . , L15a to b may be dependent on the inherent impedance of the transmission line itself used for the first transmission line 320. Alternatively, each of the inductive components L11a to b, L12a to b, . . . , L15a to b may be an inductor element provided in each section of the transmission line used for the first transmission line 320.

In a connected state between the terminals P1 and P2, three or more first switching elements in a disconnected state are connected to three or more first connection points. In this manner, the first transmission line 320 is configured to have a characteristic impedance consistent with the characteristic impedance Z0 of the external transmission line according to the inductive component of the first transmission line 320 and the capacitance component due to the parasitic capacitances of the three or more first switching elements in the disconnected state.

More specifically, the section x (x=1 to N, and N is 5 in the example in the present drawing) of the first transmission line 320 in the first connecting unit 110 can be represented by an equivalent circuit in which the capacitance component Coff by the shunt-connected switch Q1Sx is connected to the inductive components L1xa to b. The first connecting unit 110 can be viewed as a pseudo-distributed constant line where such equivalent circuits for each section a distributed on the line.

If the magnitude of the inductive components L1xa to b in the section x is L(=2Lt), and the magnitude of the capacitance component connected to the first connection point of the section x is C(=Coff), the section x has an impedance of \sqrt{(L/C)}. The magnitude of the inductive component and the magnitude of the capacitance component within each section are defined, so that all sections of the first transmission line 320 in the first connecting unit 110 have an impedance consistent with the specified impedance Z0 of the external transmission line. Herein, the impedance of each section being consistent with the characteristic impedance Z0 of the external transmission line means a state in which the impedance of each section is identical or identical by design to the characteristic impedance Z0, but some implementation errors can exist.

The impedance of each section may be adjusted by adjusting the magnitude of the inductive component by adjusting the length of each section, and by adjusting the magnitude of the capacitance component by adjusting the gate width of each of the shunt-type switches Q1S1 to Q1S5. This allows the first connecting unit 110 to function as a pseudo-distributed constant line with a characteristic impedance consistent with the characteristic impedance Z0 when the terminals P1 and P2 are in a connected state, providing a loop back path with smaller loss characteristics.

The magnitude and length of the inductive component of each section of the first transmission line 320 in the first connecting unit 110, and the magnitude of the capacitance component of each section may be substantially identical (identical except for implementation errors). Alternatively, the magnitude of the inductive component and the magnitude of the capacitance component of each section of the first transmission line 320 in the first connecting unit 110 may be different in the magnitude for each section while still keeping the characteristic impedance of each section consistent.

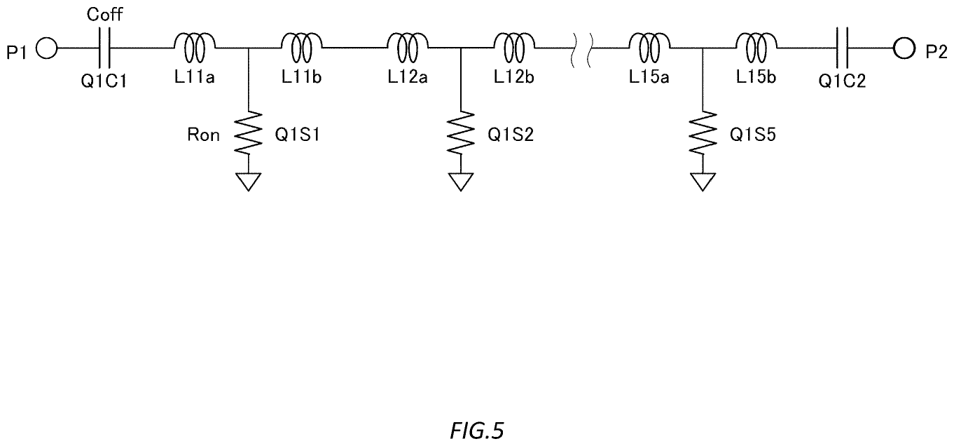

FIG. 5 illustrates an equivalent circuit in a disconnected state between the terminals P1 and P2 of the first connecting unit 110 according to the present embodiment. In a disconnected state between the terminals P1 and P2, the switches Q1C1 to Q1C2 are turned off and can be equivalently represented as capacitors with a capacitance value Coff corresponding to the parasitic capacitance when off. The switches Q1S1 to Q1S5 are turned on and can be equivalently represented as a resistor with a resistance value Ron corresponding to the on-resistance.

In this equivalent circuit, if a shunt-type switch Q1Sx with a gate width Wg is provided in each of N sections of the first transmission line 320 in the first connecting unit 110, the entire first connecting unit 110 is equivalent to be provided with a shunt-type switch with the gate width Wg×N. Accordingly, even though the gate width Wg of individual shunt-type switches Q1Sx is relatively small, high isolation characteristics can be achieved for the entire first connecting unit 110. Furthermore, if the characteristic impedance of the first transmission line 320 itself is greater than the characteristic impedance Z0 of the external transmission line, the isolation characteristics of the first connecting unit 110 can be further enhanced.

In the first connecting unit 110 shown above, there are three or more shunt-type switches Q1Sx that switch the connection of three or more first connection points to the reference potential. Alternatively, the first connecting unit 110 may have the first transmission line 320 divided into two sections, and each of the two sections of the first transmission line 320 in the first connecting unit 110 may have an impedance consistent with the characteristic impedance Z0 of the external transmission line in an OFF state of the shunt-type switches Q1S1 to 2.

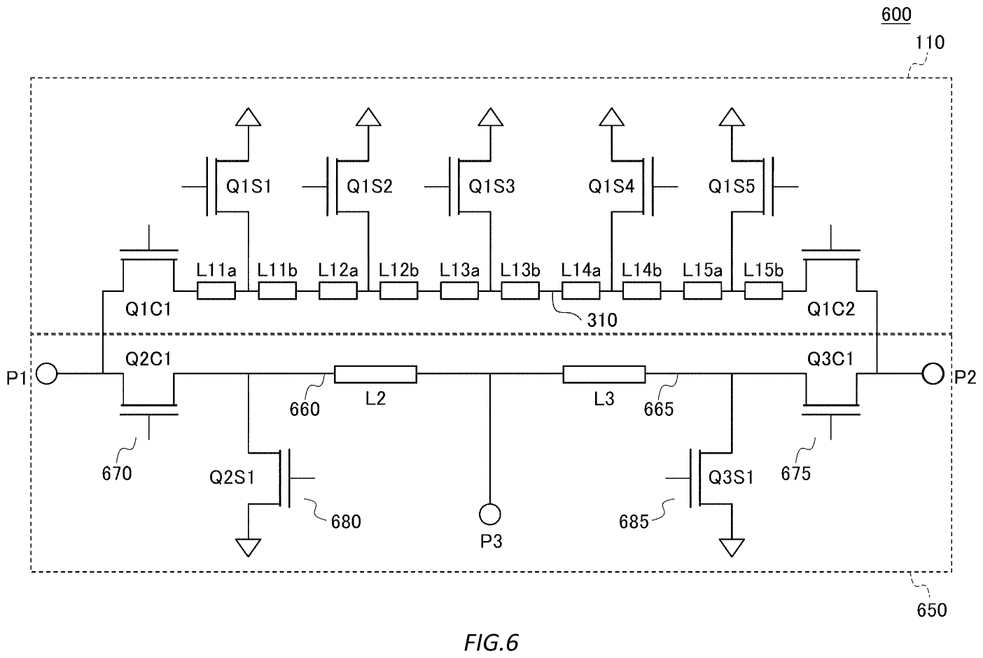

FIG. 6 illustrates a circuit configuration of the connecting device 600 according to a first modification example in the present embodiment. The connecting device 600 according to the present modification example includes the first connecting unit 110 and the second connecting unit 650. The first connecting unit 110 has the same configuration as the first connecting unit 110 in FIG. 3, so the explanation is omitted except for the following differences.

The second connecting unit 650 has a second transmission line 660, a third transmission line 665, a second connection switching unit 670, a third connection switching unit 675, a second ground switching unit 680 and a third ground switching unit 685. The second transmission line 660 functions as a path that electrically connects between the terminal P1 and the terminal P3. The third transmission line 665 functions as a path that electrically connects between the terminal P2 and the terminal P3.

The second connection switching unit 670 switches the connection between the terminal P1 and the terminal P3 via the second transmission line 660. In the example in the present drawing, the second connection switching unit 670 includes the switch Q2C1 that switches the connection between the terminal P1 and the second transmission line 660.

The third connection switching unit 675 switches the connection between the terminal P2 and the terminal P3 via the third transmission line 665. In the example in the present drawing, the third connection switching unit 675 includes the switch Q3C1 that switches the connection the terminal P2 and the third transmission line 665.

The second ground switching unit 680 includes a shunt-type switch Q2S1 that switches the connection of the end on the terminal P1 side in the second transmission line 660 to the reference potential. In the present modification example, the second ground switching unit 680 switches the connection of a second connection point at a position with a distance equal to ¼ of the wavelength of the signal passing through the terminal P3 away from the terminal P3 in the second transmission line 660 to the reference potential.

The third ground switching unit 685 includes the shunt-type switch Q3S1 that switches the connection of the end on the terminal P2 side in the third transmission line 665 to the reference potential. In the present modification example, the third ground switching unit 685 switches the connection of the third connection point at a position with a distance equal to ¼ of the wavelength of the signal passing through the terminal P3 away from the terminal P3 in the third transmission line 665 to the reference potential.

In the present modification example, the second connecting unit 650 can enhance the isolation characteristics of the transceived signal with a predetermined frequency, which passes through the terminal P3 by using the switch that uses the λ/4 line between the terminal P3 and the terminal P1 or P2. Accordingly, the second connecting unit 650 can reduce the amount of leakage of the signal passing through the terminal P3 for a terminal among the terminals P1 and P2 that is not connected to the terminal P3.

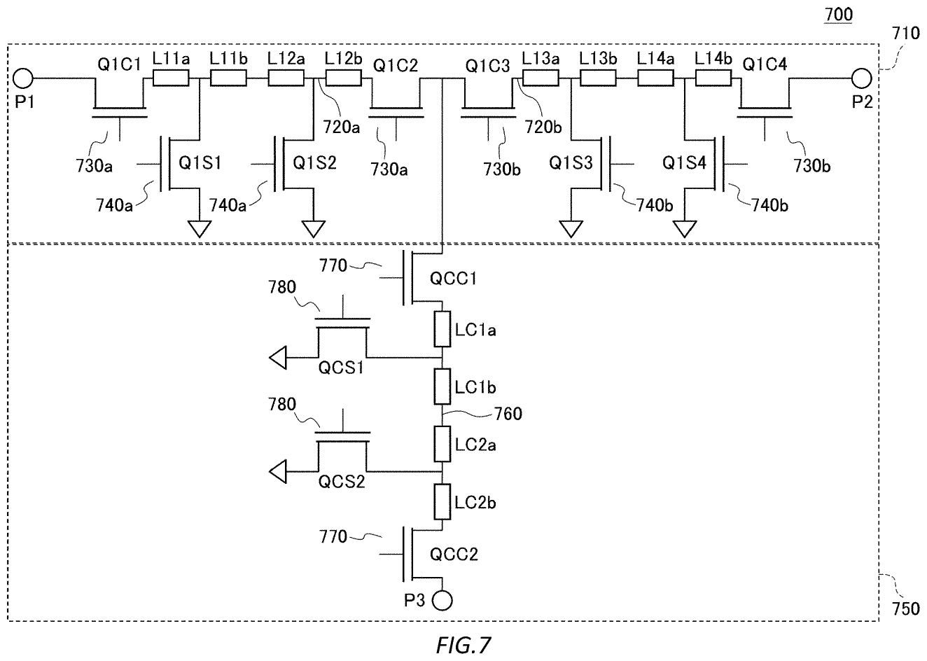

FIG. 7 illustrates a circuit configuration of a connecting device 700 according to a second modification example in the present embodiment. The connecting device 700 according to the present modification example includes the first connecting unit 710 and the second connecting unit 750. The first connecting unit 710 has first transmission lines 720a to b, first connection switching units 730a to b, and first ground switching units 740a to b.

The first transmission lines 720a to b function as the loop back path that transmits the transmission signal from the terminal P1 to the terminal P2 as a result of the electrical connection between the terminal P1 and the terminal P2. Hereinafter, the first transmission lines 720a to b are also represented as the “first transmission line 720”.

The first connection switching units 730a to b switch the connection between the terminal P1 and the terminal P2 via the first transmission lines 720a to b. Hereinafter, the first connection switching units 730a to b are also represented as the “first connection switching unit 730”. The first connection switching unit 730a switches the connection between the terminal P1 and the branching point toward the terminal P3 (the branching point between the switches Q1C2 and Q1C3). The first connection switching unit 730a includes a switch Q1C1 that switches the connection between the terminal P1 and the first transmission line 720a, and a switch Q1C2 that switches the connection between the first transmission line 720a and the branching point.

The first connection switching unit 730b switches the connection between the terminal P2 and the branching point toward the terminal P3. The first connection switching unit 730b includes a switch Q2C4 that switches the connection between the terminal P2 and the first transmission line 720b, and a switch Q2C3 that switches the connection between the first transmission line 720b and the branching point.

When connecting between the terminal P1 and the terminal P2, the first connection switching unit 730 turns on each switch of the first connection switching unit 730a and connects between the terminal P1 and the branching point via the first transmission line 720a, and turns on each switch of the first connection switching unit 730b and connects between the terminal P2 and the branching point via the first transmission line 720b under control by the control circuit. When connecting between the terminal P1 and the terminal P3, the first connection switching unit 730 connects the terminal P1 and the branching point to the first transmission line 720a with the first connection switching unit 730a, and disconnects the terminal P2 and the branching point from the first transmission line 720b with the first connection switching unit 730b. When connecting between the terminal P2 and the terminal P3, the first connection switching unit 730 disconnects the terminal P1 and the branching point from the first transmission line 720a and connects the terminal P2 and the branching point to the first transmission line 720b.

The first ground switching unit 740a switches the connection of each of two or more first connection points at different positions in the first transmission line 720a to the reference potential. The first ground switching unit 740a includes shunt-type switches Q1Sx (shunt-type switches Q1S1 and Q1S2 in the example in the present drawing) arranged between each first connection point of two or more sections obtained by dividing the first transmission line 720a into the two or more sections and the reference potential. In the present embodiment, when the terminals P1 and P3 are connected, the first connecting unit 710 may have an impedance consistent with the characteristic impedance Z0 of the external transmission line when each section of the first transmission line 720a is in an ON state of the shunt-type switches Q1Sx, similar to the pseudo-distributed constant line shown in FIG. 4. The first ground switching unit 740a may include three or more shunt-type switches Q1Sx that connect each of three or more first connection points at different positions in the first transmission line 720a to the reference potential.

The first ground switching unit 740b switches the connection of each of two or more first connection points at different positions in the first transmission line 720b to the reference potential. The first ground switching unit 740b includes shunt-type switches Q1Sx (in the example in the present drawing, the shunt-type switches Q1S3 and Q1S4) arranged between each first connection point of the two or more sections obtained by dividing the first transmission line 720b into the two or more sections and the reference potential. In the present embodiment, when the terminals P2 and P3 are connected, the first connecting unit 710 may have an impedance consistent with the characteristic impedance Z0 of the external transmission line when each section of the first transmission line 720b is in an ON state of the shunt-type switches Q1Sx, similar to the pseudo-distributed constant line shown in FIG. 4. The first ground switching unit 740b may include three or more shunt-type switches Q1Sx that connect each of three or more first connection points at different positions in the first transmission line 720b to the reference potential.

When connecting between the terminal P1 and the terminal P2, the first ground switching unit 740 connects between each first connection point of the first transmission line 720 and the reference potential under control by the control circuit. When connecting between the terminal P1 and the terminal P3, the first ground switching unit 740 disconnects between each first connection point on the terminal P1 side from the branching point in the first transmission line 720 (that is, each first connection point of the first transmission line 720a) and the reference potential, and connects between each first connection point on the terminal P2 side from the branching point in the first transmission line 720 (that is, each first connection point of the first transmission line 720b) and the reference potential. When connecting between the terminal P2 and the terminal P3, the first ground switching unit 740 connects between each first connection point on the terminal P1 side from the branching point in the first transmission line 720 and the reference potential, and disconnects between each first connection point on the terminal P2 side from the branching point in the first transmission line 720 and the reference potential.

The second connecting unit 750 has a common transmission line 760, a common connection switching unit 770 and a common ground switching unit 780. The common transmission line 760 is a transmission line shared by the connection between the terminal P1 and the terminal P3 and the connection between the terminal P2 and the terminal P3.

The common connection switching unit 770 switches the connection between the branching point located in the middle of the first transmission line 320 and the terminal P3 via the common transmission line 760. The common connection switching unit 770 includes a switch QCC1 that switches the connection between the branching point and the common transmission line 760, and a switch QCC2 that switches the connection between the common transmission line 760 and the terminal P3.

When connecting between the terminal P1 and the terminal P2, the common connection switching unit 770 turns off each switch and disconnects between the terminal P3 and the branching point under control by the control circuit. When connecting between the terminal P1 or P2 and the terminal P3, the common connection switching unit 770 turns on each switch and connects between the terminal P3 and the branching point.

The common ground switching unit 780 switches the connection of each of two or more common connection points at different positions in the common transmission line 760 to the reference potential. The common ground switching unit 780 includes shunt-type switches QCSx arranged between each common connection point of two or more sections obtained by dividing the common transmission line 760 into the two or more sections and the reference potential. In present modification example, when the terminal P1 or P2 and the terminal P3 are connected, the common ground switching unit 780 may have an impedance consistent with the characteristic impedance Z0 of the external transmission line when each section of the common transmission line 760 is in an ON state of the shunt-type switches QCSx, similar to the pseudo-distributed constant line shown in FIG. 4. The common ground switching unit 780 may include three or more shunt-type switches QCSx that connect each of the three or more common connection points at different positions in the common transmission line 760 to the reference potential.

When connecting between the terminal P1 and the terminal P2, the common ground switching unit 780 turns on each switch and connects between each common connection point of the common transmission line 760 and the reference potential under control by the control circuit. When connecting between the terminal P1 or P2 and the terminal P3, the common ground switching unit 780 turns off each switch and disconnects between each common connection point of the common transmission line 760 and the reference potential.

Even if connecting between either two terminals among the terminals P1, P2 and P3, the connecting device 700 according to the present modification example can connect between the two terminals due to the pseudo-distributed constant line similar to that shown in FIG. 4. This allows the connecting device 700 to provide a path with smaller loss characteristics even if connecting between either two terminals among the terminals P1, P2 and P3. This also allows the connecting device 700 to disconnect the rest terminal due to the equivalent circuit as shown in FIG. 5 even if connecting between either two terminals among the terminals P1, P2 and P3. This allows the connecting device 700 to enhance the isolation characteristics between the two terminals that are connected and the rest terminal.

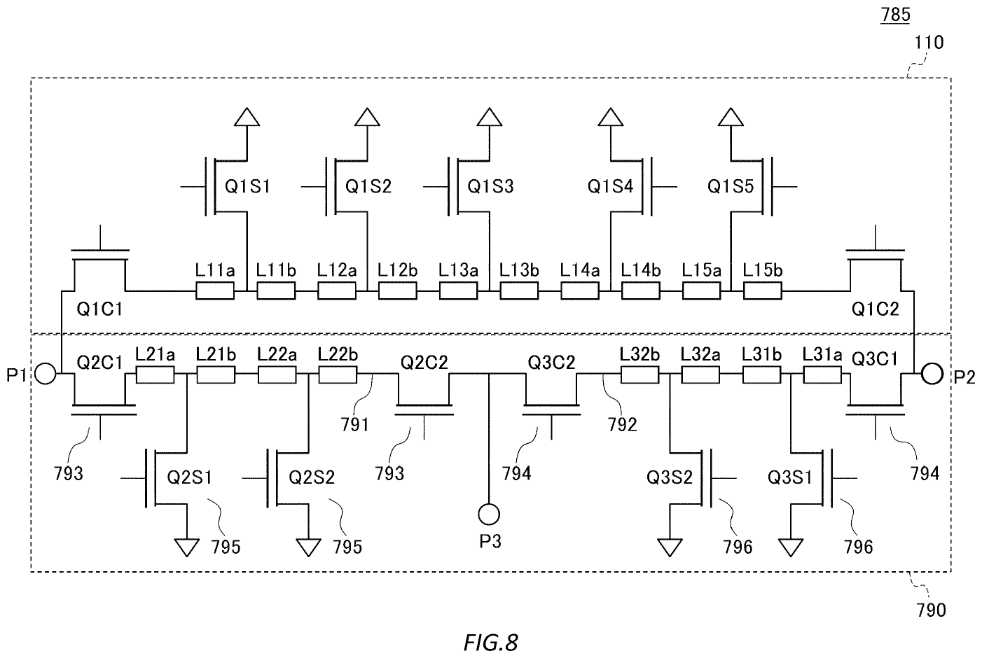

FIG. 8 illustrates a circuit configuration of a connecting device 785 according to a third modification example in the present embodiment. The connecting device 785 according to the present modification example includes the first connecting unit 110 and the second connecting unit 790. The first connecting unit 110 has the same configuration as the first connecting unit 110 in FIG. 3, so the explanation is omitted except for the following differences.

The second connecting unit 790 has a second transmission line 791, a third transmission line 792, a second connection switching unit 793, a third connection switching unit 794, a second ground switching unit 795 and a third ground switching unit 796. The second transmission line 791 functions as a path that electrically connects between the terminal P1 and the terminal P3. The third transmission line 792 functions as a path that electrically connects between the terminal P2 and the terminal P3.

The second connection switching unit 793 switches the connection between the terminal P1 and the terminal P3 via the second transmission line 791. In the example in the present drawing, the second connection switching unit 793 includes a switch Q2C1 that switches the connection between the terminal P1 and the second transmission line 791, and a switch Q2C2 that switches the connection between the second transmission line 791 and the terminal P3. When connecting between the terminal P1 and the terminal P3, the second connection switching unit 793 connects the terminal P1 and the terminal P3 to the second transmission line 791 under control by the control circuit. When not connecting between the terminal P1 and the terminal P3, the second connection switching unit 793 disconnects the terminal P1 and the terminal P3 from the second transmission line 791.

The third connection switching unit 794 switches the connection between the terminal P2 and the terminal P3 via the third transmission line 792. In the example in the present drawing, the third connection switching unit 794 includes a switch Q3C1 that switches the connection between the terminal P2 and the third transmission line 792, and the switch Q3C2 that switches the connection between the third transmission line 792 and the terminal P3. When connecting between the terminal P2 and the terminal P3, the third connection switching unit 794 connects the terminal P2 and the terminal P3 to the third transmission line 792 under control by the control circuit. When not connecting between the terminal P2 and the terminal P3, the third connection switching unit 794 disconnects the terminal P2 and the terminal P3 from the third transmission line 792.

The second ground switching unit 795 switches the connection of each of the two or more second connection points at different positions in the second transmission line 791 to the reference potential. In the example in the present drawing, the second ground switching unit 795 includes shunt-type switches Q2Sx (In the example in the present drawing, the shunt-type switches Q1S1 and Q1S2) arranged between each second connection point of two or more sections obtained by dividing the second transmission line 791 into the two or more sections and the reference potential. In the present modification example, when the terminals P1 and P3 are connected, the second connecting unit 790 may have an impedance consistent with the characteristic impedance Z0 of the external transmission line when each section of the second transmission line 791 is in an OFF state of the shunt-type switches Q2Sx, similar to the pseudo-distributed constant line shown in FIG. 4. The second ground switching unit 795 may include three or more shunt-type switches Q2Sx that connect each of three or more second connection points at different positions in the second transmission line 791 to the reference potential.

When connecting between the terminal P1 and the terminal P3, the second ground switching unit 795 turns off each switch and disconnects between each second connection point of the second transmission line 791 and the reference potential under control by the control circuit. When disconnecting between the terminal P1 and the terminal P3, the second ground switching unit 795 turns on each switch and connects between each second connection point of the second transmission line 791 and the reference potential.

The third ground switching unit 796 switches the connection of each of two or more third connection points at different positions in the third transmission line 792 to the reference potential. In the example in the present drawing, the third ground switching unit 796 includes shunt-type switches Q3Sx arranged between each third connection point of two or more sections obtained by dividing the third transmission line 792 into the two or more sections and the reference potential. In the present modification example, when the terminals P2 and P3 are connected, the second connecting unit 790 may have an impedance consistent with the characteristic impedance Z0 of the external transmission line when each section of the third transmission line 792 is in an OFF state of the shunt-type switches Q3Sx, similar to the pseudo-distributed constant line shown in FIG. 4. The third ground switching unit 796 may include three or more shunt-type switches Q3Sx that connect each of three or more third connection points at different positions in the third transmission line 792 to the reference potential.

When connecting between the terminal P2 and the terminal P3, the third ground switching unit 796 turns off each switch and disconnects between each third connection point of the third transmission line 792 and the reference potential under control by the control circuit. When disconnecting between the terminal P2 and the terminal P3, the third ground switching unit 796 turns on each switch and connects between each third connection point of the third transmission line 792 and the reference potential.

Even if connecting between either two terminals among the terminals P1, P2 and P3, the connecting device 785 according to the present modification example can connect between the two terminals due to the pseudo-distributed constant line similar to that shown in FIG. 4. This allows the connecting device 785 to provide a path with smaller loss characteristics even if connecting between either two terminals among the terminals P1, P2 and P3. This also allows the connecting device 785 to disconnect the rest terminal due to the equivalent circuit as shown in FIG. 5 even if connecting between either two terminals among the terminals P1, P2 and P3. This allows the connecting device 785 to enhance the isolation characteristics between the two terminals that are connected and the rest terminal.

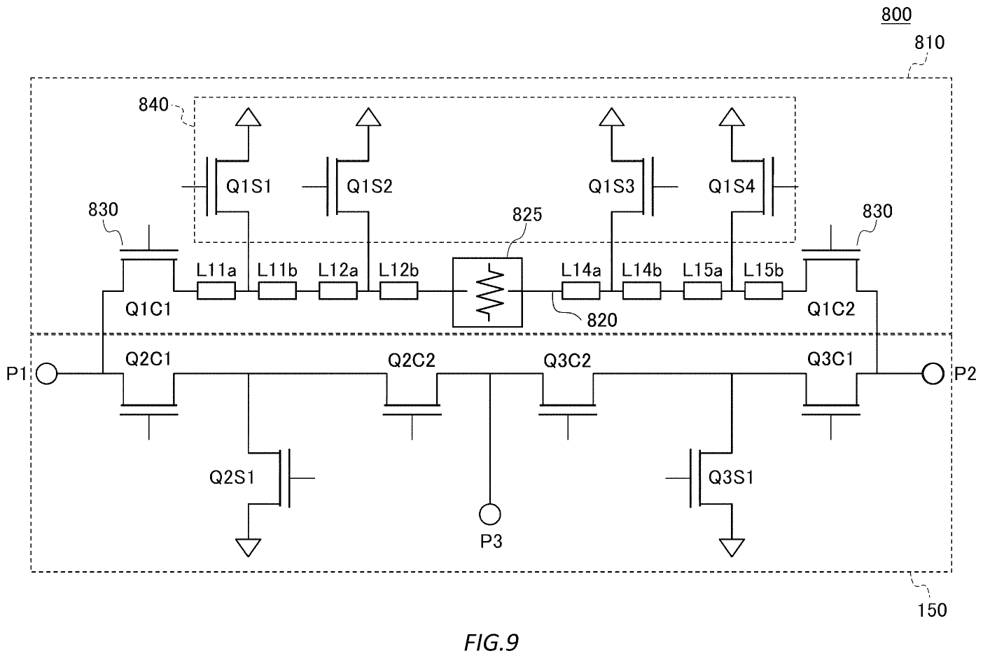

FIG. 9 illustrates a circuit configuration of a connecting device 800 according to a fourth modification example in the present embodiment. The connecting device 800 includes the first connecting unit 810 and the second connecting unit 150 according to the present modification example. The second connecting unit 150 has the same configuration as the second connecting unit 150 in FIG. 3, so the explanation is omitted except for the following differences.

The first connecting unit 810 has a first transmission line 820, a first connection switching unit 830 and a first ground switching unit 840. The first transmission line 820 functions as a loop back path that transmits the transmission signal from the terminal P1 to the terminal P2 as a result of the electrical connection between the terminal P1 and the terminal P2. In the present modification example, the first transmission line 820 includes an attenuator 825 on the path. The attenuator 825 attenuates the transmission signal from the terminal P1 and transmits it to the terminal P2. The first connection switching unit 830 and the first ground switching unit 840 have the same configurations and functions as the first connection switching unit 330 and the first ground switching unit 340 in FIG. 3, so the explanations are omitted.

The connecting device 800 according to the present modification example may be used in a communication device or the like that transmits a relatively strong transmission signal to an external device far away via the connecting device 800, and receives a received signal that has been attenuated during transmission from the external device. This allows the connecting device 800 to loop back the transmission signal that has been attenuated, similar to the received signal from the external device by attenuating the transmission signal in the loop back path.

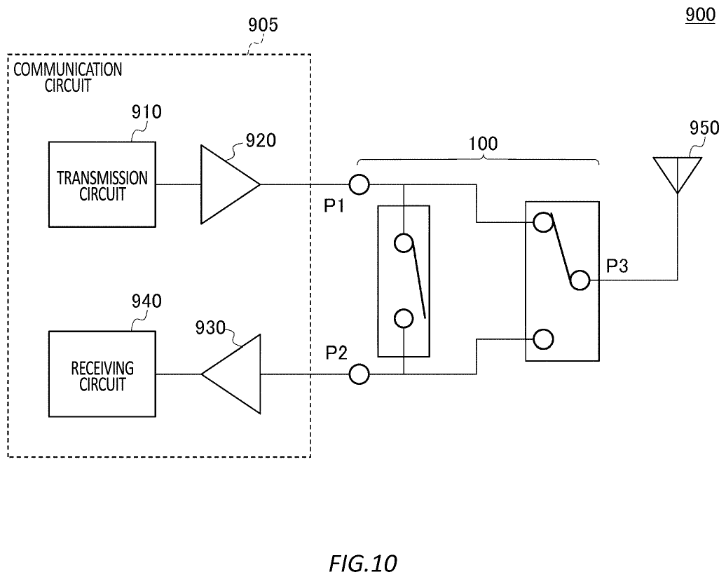

FIG. 10 illustrates a configuration of a communication device 900 according to a fifth modification example in the present embodiment. The communication device 900 includes a communication circuit 905, a connecting device 100 and an antenna 950. The communication circuit 905 has a transmission circuit 910, an amplifier 920, an amplifier 930, a receiving circuit 940 and an antenna 950.

The transmission circuit 910 conducts transmission process of the transmission signal to be transmitted from the communication device 900 to another device and outputs the transmission signal. The amplifier 920 is connected to the transmission circuit 910, and amplifies the transmission signal from the transmission circuit 910 to supply it to the terminal P1 of the connecting device 100.

The amplifier 930 is connected to the terminal P2 of the connecting device 100 and amplifies the received signal from the terminal P2. The receiving circuit 940 is connected to the terminal P2 of the connecting device 100 via the amplifier 930, and inputs the received signal amplified by the amplifier 930 to conduct the receiving process.

The connecting device 100 is identical to the connecting device 100 in FIG. 3. The connecting device 100 has its terminal P1 connected to the output terminal of the transmission signal in the transmission circuit 910 via the amplifier 920, its terminal P2 connected to the input terminal of the received signal in the receiving circuit 940 via the amplifier 930, and its terminal P3 connected to the antenna 950.

The antenna 950 is connected to the terminal P3 of the connecting device 100, and is connected by wireless to another device that becomes a generation source of a received signal from the terminal P1 to the destination of the transmission signal or the terminal P2. In the present modification example, the antenna 950 receives the transmission signal from the transmission circuit 910 from the terminal P3, and emits the wireless transmission signal. The antenna 950 receives the wireless received signal from another device and supplies it as a received signal to the terminal P3.

The communication device 900 may be connected to another device wired by electrical cables instead of the antenna 950, and may exchange the electrical transmission signal and received signal with another device. The communication device 900 may include, for example, an opto-electric and electro-optical conversion circuit instead of the antenna 950, and may exchange an optical transmission signal and an optical received signal with the another device.

The communication device 900 shown above can loop back the transmission signal from the transmission circuit 910 to the receiving circuit 940 in addition to exchanging the transmission signal and the received signal with another device. Accordingly, the communication device 900 can conduct a self-test or a BIST (Built-In Self Test) to know whether the signal, which is transmitted from the transmission circuit 910 and looped back to the receiving circuit 940, is successfully received by the receiving circuit 940. The communication device 900 may also use the connecting device 600 in FIG. 6, the connecting device 700 in FIG. 7, the connecting device 785 in FIG. 8 or the connecting device 800 in FIG. 9 instead of the connecting device 100.

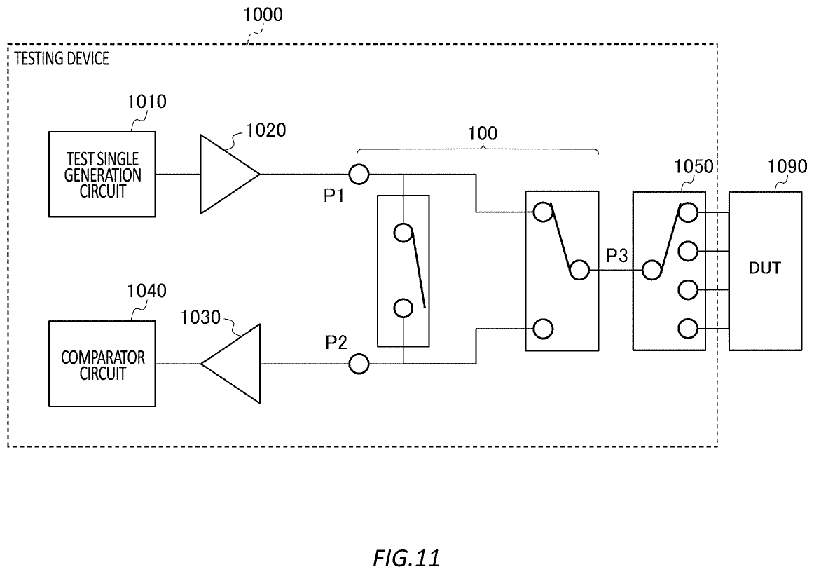

FIG. 11 illustrates a configuration of a testing device 1000 according to a sixth modification example in the present embodiment. The testing device 1000 conducts the test of a DUT (Device Under Test) 1090. The testing device 1000 includes a test signal generation circuit 1010, an amplifier 1020, an amplifier 1030, a comparator circuit 1040, a connecting device 100 and a switch 1050.

The test signal generation circuit 1010 generates a test signal to test the DUT 1090. The amplifier 1020 is connected to the test signal generation circuit 1010, and amplifies the test signal from the test signal generation circuit 1010 to supply it to the terminal P1 of the connecting device 100.

The amplifier 1030 is connected to the terminal P2 of the connecting device 100, and amplifies the response signal output by the DUT 1090 according to the test signal. The comparator circuit 1040 is connected to the terminal P2 of the connecting device 100 via the amplifier 1030 and compares the response signal amplified by the amplifier 1030 to an expected value. The testing device 1000 may determine the DUT 1090 to be non-defective when each response signal output by the DUT 1090 for each test signal supplied to the DUT 1090 during the test matches the expected value for each response signal. The testing device 1000 may determine the DUT 1090 to be defective when the response signal output by the DUT 1090 for any test signal supplied to the DUT 1090 during the test does not match the corresponding expected value.

The connecting device 100 is identical to the connecting device 100 in FIG. 3. The connecting device 100 has its terminal P1 connected to the output terminal of the test signal in the test signal generation circuit 1010 via the amplifier 1020, its terminal P2 connected to the input terminal of the response signal in the comparator circuit 1040 via the amplifier 1030, and its terminal P3 connectable to the terminal of the DUT 1090.

The switch 1050 is connected between the terminal P3 of the connecting device 100 and a plurality of terminals (four terminals in the example in the present drawing) of the DUT 1090, and switches the connection of the terminal P3 to either terminal among the plurality of terminals of the DUT 1090. The switch 1050 may switch the connection of the terminal P3 to either terminal of the DUT 1090 according to test contents under control of the control device of the testing device 1000.

To simplify the explanations in the present drawing, the testing device 1000 is illustrated to be a configuration only including one set of a test signal generation circuit 1010, an amplifier 1020, an amplifier 1030, a comparator circuit 1040, a connecting device 100 and a switch 1050. Alternatively, the testing device 1000 has a plurality of the above set, and each set may be connected to terminals with the DUT 1090 different from each other.

The testing device 1000 shown above can loop back the transmission signal from the test signal generation circuit 1010 to the comparator circuit 1040 in addition to exchanging the test signal and the response signal with the DUT 1090. Accordingly, the testing device 1000 can conduct a self-test or a BIST (Built-In Self Test) to know whether the signal, which is transmitted from the test signal generation circuit 1010 and looped back to the comparator circuit 1040, is successfully received and determined to be normal by the comparator circuit 1040. The testing device 1000 may also use the connecting device 600 in FIG. 6, the connecting device 700 in FIG. 7, the connecting device 785 in FIG. 8 or the connecting device 800 in FIG. 9 instead of the connecting device 100.

FIG. 10 and FIG. 11 illustrate examples of using the connecting device 100 to the communication device 900 and the testing device 1000, but the connecting device 100 may be used in various devices. In this case, in the connecting device 100, the terminal P1 may be connected to the transmission circuit of the first device, the terminal P2 may be connected to the receiving circuit of the first device, and the terminal P3 may be connected to the transceiver circuit of the second device. Then the first connecting unit 110 inside the connecting device 100 provides a loop back path from the transmission circuit of the first device to the receiving circuit of the first device by connecting between the terminal P1 and the terminal P2 via the first transmission line 320.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: amplifier; 20: amplifier; 100: connecting device; 110: first connecting unit; 150: second connecting unit; 200: connecting device; 210: first connecting unit; 220: first transmission line; 230: first connection switching unit; 240: first ground switching unit; 250: second connecting unit; 260: second transmission line; 265: third transmission line; 270: second connection switching unit; 275: third connection switching unit; 280: second ground switching unit; 285: third ground switching unit; 320: first transmission line; 330: first connection switching unit; 340: first ground switching unit; 600: connecting device; 650: second connecting unit; 660: second transmission line; 665: third transmission line; 670: second connection switching unit; 675: third connection switching unit; 680: second ground switching unit; 685: third ground switching unit; 700: connecting device; 710: first connecting unit; 720a to b: first transmission line; 730 a to b: first connection switching unit; 740a to b: first ground switching unit; 750: second connecting unit; 760: common transmission line; 770: common connection switching unit; 780: common ground switching unit; 785: connecting device; 790: second connecting unit; 791: second transmission line; 792: third transmission line; 793: second connection switching unit; 794: third connection switching unit; 795: second ground switching unit; 796: third ground switching unit; 800: connecting device; 810: first connecting unit; 820: first transmission line; 825: attenuator; 830: first connection switching unit; 840: first ground switching unit; 900: communication device; 905: communication circuit; 910: transmission circuit; 920: amplifier; 930: amplifier; 940: receiving circuit; 950: antenna; 1000: testing device; 1010: test signal generation circuit; 1020: amplifier; 1030: amplifier; 1040: comparator circuit; 1050: switch; 1090: DUT.

What is claimed is:

1. A connecting device, comprising:
a first connecting unit that switches a connection between a first terminal and a second terminal; and
a second connecting unit that switches a connection between the first terminal or the second terminal and a third terminal,
wherein the first connecting unit has:
a first transmission line;
a first connection switching unit that switches the connection between the first terminal and the second terminal via the first transmission line; and
a first ground switching unit that switches a connection of each of three or more first connection points at different positions in the first transmission line to a reference potential.

2. The connecting device according to claim 1, wherein the first ground switching unit connects each of the three or more first connection points to a reference potential when there is no connection between the first terminal and the second terminal.

3. The connecting device according to claim 2, wherein the second connecting unit switches a connection of the third terminal to either the first terminal or the second terminal when there is no connection between the first terminal and the second terminal.

4. The connecting device according to claim 3, wherein the second connecting unit has:
a second transmission line;
a third transmission line;
a second connection switching unit that switches a connection between the first terminal and the third terminal via the second transmission line; and
a third connection switching unit that switches a connection between the second terminal and the third terminal via the third transmission line.

5. The connecting device according to claim 4, wherein the second connecting unit further has:
a second ground switching unit that switches a connection of each of three or more second connection points at different positions in the second transmission line to a reference potential; and
a third ground switching unit that switches a connection of each of three or more third connection points at different positions in the third transmission line to a reference potential.

6. The connecting device according to claim 4, wherein the second connecting unit has:
a second ground switching unit that switches a connection of a second connection point at a position with a distance equal to ¼ of a wavelength of a signal passing through the third terminal away from the third terminal in the second transmission line to a reference potential; and
a third ground switching unit that switches a connection of a third connection point at a position with a distance equal to ¼ of a wavelength of a signal passing through the third terminal away from the third terminal in the third transmission line to a reference potential.

7. The connecting device according to claim 3, wherein:
the second connecting unit has:
a common transmission line shared by a connection between the first terminal and the third terminal, and a connection between the second terminal and the third terminal; and
a common connection switching unit that switches a connection between a branching point located in middle of the first transmission line and the third terminal via the common transmission line,
the first connection switching unit
connects the first terminal to the first transmission line and disconnects the second terminal from the first transmission line when it is connected between the first terminal and the third terminal; and
disconnects the first terminal from the first transmission line and connects the second terminal to the first transmission line when it is connected between the second terminal and the third terminal,
the first ground switching unit:
disconnects between each first connection point on a side of the first terminal from the branching point in the first transmission line and a reference potential, and connects between each first connection point on a side of the second terminal from the branching point in the first transmission line and a reference potential, when it is connected between the first terminal and the third terminal; and
connects between each first connection point on a side of the first terminal from the branching point in the first transmission line and a reference potential, and disconnects between each first connection point on a side of the second terminal from the branching point in the first transmission line and a reference potential, when it is connected between the second terminal and the third terminal.

8. The connecting device according to claim 7, wherein the second connecting unit further has a common ground switching unit that switches a connection of each of three or more common connection points at different positions in the common transmission line to a reference potential.

9. The connecting device according to claim 1, wherein:
the first ground switching unit has three or more first switching elements that connect or disconnect between each of the three or more first connection points and the reference potential;
the first transmission line has a characteristic impedance higher than a characteristic impedance of an external transmission line connected to the first terminal due to an inductive component; and
the first transmission line where the three or more first switching elements in a disconnected state are connected to the three or more first connection points has a characteristic impedance consistent with the characteristic impedance of the external transmission line due to the inductive component of the first transmission line and a capacitance component due to a parasitic capacitance of the three or more first switching elements in the disconnected state.

10. The connecting device according to claim 1, wherein:
the first terminal is connected to a transmission circuit of a first device;
the second terminal is connected to a receiving circuit of the first device;
the third terminal is connected to a transceiver circuit of a second device; and
the first connecting unit provides a loop back path from the transmission circuit of the first device to the receiving circuit of the first device by connecting between the first terminal and the second terminal via the first transmission line.

11. A testing device, comprising:
a test signal generation circuit that generates a test signal for testing a device under test;
a comparator circuit that compares a response signal output by the device under test to an expected value according to the test signal; and
a connecting device where a first terminal is connected to an output terminal of the test signal in the test signal generation circuit, a second terminal is connected to an input terminal of the response signal in the comparator circuit, and a third terminal is connectable to a terminal of the device under test,
wherein the connecting device has:
a first connecting unit that switches a connection between the first terminal and the second terminal; and
a second connecting unit that switches a connection between the first terminal or the second terminal, and the third terminal,
wherein the first connecting unit has:
a first transmission line;
a first connection switching unit that switches the connection between the first terminal and the second terminal via the first transmission line; and
a first ground switching unit that switches a connection of each of three or more first connection points at different positions in the first transmission line to a reference potential.

12. A communication device, comprising:
a communication circuit with a transmission circuit that outputs a transmission signal and a receiving circuit that inputs a received signal; and
a connecting device where a first terminal is connected to an output terminal of the transmission signal in the transmission circuit, a second terminal is connected to an input terminal of the received signal in the receiving circuit, and a third terminal is connected to a destination of the transmission signal or a generation source of the received signal in a wired or wireless manner,
wherein the connecting device has:
a first connecting unit that switches a connection between the first terminal and the second terminal; and
a second connecting unit that switches a connection between the first terminal or the second terminal and the third terminal,
wherein the first connecting unit has:
a first transmission line;
a first connection switching unit that switches the connection between the first terminal and the second terminal via the first transmission line; and
a first ground switching unit that switches a connection of each of three or more first connection points at different positions in the first transmission line to a reference potential.
